(19) United States
(12) Patent Application Publication
(10) Pub. No.: US 2015/0194307 A1
(43) Pub. Date: Jul. 9, 2015

(54) STRAINED FIN STRUCTURES AND METHODS OF FABRICATION

(71) Applicant: GLOBALFOUNDRIES Inc., Grand Cayman (KY)

(72) Inventors: Churamani GAIRE, Clifton Park, NY (US); Bharat KRISHNAN, Mechanicville, NY (US); Jin Ping LIU, Ballston Lake, NY (US)

(73) Assignee: GLOBALFOUNDRIES INC., Grand Cayman (KY)

(21) Appl. No.: 14/147,666

(22) Filed: Jan. 6, 2014

(51) Int. Cl. H01L 21/02; H01L 27/092; H01L 29/10

(52) U.S. Cl. CPC H01L 21/02381; H01L 29/1054; H01L 27/0924

(57) ABSTRACT

Methods for fabricating a strained fin structure are provided which include: providing a virtual substrate material over a substrate structure, the virtual substrate material having a virtual substrate lattice constant and a virtual substrate lattice structure; providing a first material over a region of the virtual substrate material, the first material acquiring a strained first material lattice structure by, in part, conforming to the virtual substrate lattice structure; and etching a first fin pattern into the first material. The method may include providing a second material over a second region of the virtual substrate material, the second material acquiring a strained lattice structure by, in part, conforming to the virtual substrate lattice structure, and etching a fin pattern into the second material. The resultant device may have tensile strained fin structures or compressively strained fin structures, or both.

### FIELD OF THE INVENTION

The present invention generally relates to circuit structures and methods of fabricating circuit structures, and more particularly, to strained fin circuit structures and methods of fabricating strained fin circuit structures.

### BACKGROUND

Fin field-effect transistor (FinFET) devices continue to be developed to replace conventional planar metal oxide semiconductor field-effect transistors (MOSFETs) in advanced complementary metal oxide semiconductor (CMOS) technology. As is known, the term “fin” refers to a vertical structure within or upon which are formed, for instance, one or more FinFETs or other fin devices, such as passive devices, including capacitors, diodes, etc.

### SUMMARY OF THE INVENTION

The shortcomings of the prior art are overcome and additional advantages are provided through the provision, in one aspect, of a method for fabricating a strained fin structure. The fabricating includes, for instance: providing a virtual substrate material over a substrate structure, the virtual substrate material having a virtual substrate lattice constant and a virtual substrate lattice structure; providing a first material over a region of the virtual substrate, the first material having a first material lattice constant different from the virtual substrate lattice constant, the first material acquiring a strained first material lattice structure via, in part, conforming to the virtual substrate lattice structure; and etching a first fin pattern into the first material, the first fin pattern including at least one first material fin extending above the region of the virtual substrate material.

Additional features and advantages are realized through the techniques of the present invention. Other embodiments and aspects of the invention are described in detail herein and are considered a part of the claimed invention.

### BRIEF DESCRIPTION OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIGS. 1A-1D depict one embodiment of a method of forming a virtual substrate material over a substrate structure, in accordance with one or more aspects of the present invention;

FIGS. 2A-2B depict one embodiment of a structure including a virtual substrate material over a substrate structure and a first masking material covering a portion of the virtual substrate material, with a first region of the virtual substrate material left exposed, in accordance with one or more aspects of the present invention;

FIGS. 2C-2D depict the structure of FIGS. 2A-2B after a first material has been provided over the first region of the virtual substrate material, in accordance with one or more aspects of the present invention;

FIGS. 2E-2F depict the structure of FIGS. 2C-2D with a second masking material covering the first material and a second region of the virtual substrate material exposed, in accordance with one or more aspects of the present invention;

FIGS. 2G-2H depict the structure of FIGS. 2E-2F after a second material has been provided over the second region of the virtual substrate material, in accordance with one or more aspects of the present invention;

FIGS. 2I-2J depict the structure of FIGS. 2G-2H after a fin pattern has been provided over the first and second materials over the first and second regions of the virtual substrate material, in accordance with one or more aspects of the present invention;

FIGS. 2K-2L depict the structure of FIGS. 2I-2J with the fin pattern etched into the first material and second material, in accordance with one or more aspects of the present invention; and

FIGS. 2M-2N depict the structure of FIGS. 2K-2L after the fin pattern has been removed, leaving etched first material and second material fins over the virtual substrate material, in accordance with one or more aspects of the present invention.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Generally stated, provided herein, in one aspect, is a method for facilitating fabrication of a strained fin structure. The facilitating fabricating includes, for instance: providing a virtual substrate material over a substrate structure, the virtual substrate material having a virtual substrate lattice structure and a virtual substrate lattice constant; providing a first material over a region of the virtual substrate material, the first material having a first material lattice constant different from the virtual substrate lattice constant, the first material acquiring a strained first material lattice structure via, in part, conforming to the virtual substrate lattice structure; and etching a first fin pattern into the first material, the first fin pattern including at least one first material fin extending above the region of the virtual substrate material. In one embodiment, the region of the virtual substrate material may be a first region, and the method may further include providing a second material over a second region of the virtual substrate material, the second material having a second material lattice constant different from the virtual substrate lattice constant and the first material lattice constant, the second material acquiring a strained second material lattice structure via, in part, conforming to the virtual substrate lattice structure, and the etching may further include etching a second fin pattern into the second material, the second fin pattern including at least one second material fin extending above the second region of the virtual substrate material.

In one or more embodiments the provided method for fabricating a strained fin structure may further include forming at least one fin structure with a tensile strained lattice structure over the virtual substrate material, and may also include forming at least one fin structure with a compressively strained lattice structure over the virtual substrate material. Conventional methods of fin formation may form either or both n-type and p-type fins over a substrate, such as a silicon substrate; generally, it is desirable to increase electron mobility in n-type fins and to increase hole mobility in p-type fins. Although some conventional methods may be capable of forming p-type fins with enhanced hole mobility, similar methods for forming n-type fins with enhanced electron mobility have remained challenging to achieve. Conventional strain engineering methods, for example, may form p-type fins over a silicon substrate by depositing a material with a larger lattice constant onto the silicon substrate, which has a smaller lattice constant and therefore comparatively smaller lattice structure. The deposited material may conform to the smaller lattice structure of the silicon, inducing a compressive strain into the material and thus increasing the hole mobility of that material, as may be desirable for p-type fins. Conversely, it is generally desired that n-type fins have increased electron mobility, which may be improved by inducing a tensile strain in the material forming the n-type fin. This might be achieved if the n-type fin material has a smaller lattice constant than the substrate over which the fins are formed. As n-type fins are generally formed of silicon, as are the silicon substrates they are formed over, depositing silicon on silicon may fail to produce the desired tensile strain. The methods disclosed herein overcome these limitations of the art and provide, in part, a process for forming n-type fin structures with enhanced electron mobility as well as p-type fin structures with enhanced hole mobility.

Also provided herein, in another aspect, is a device, the device including: a substrate structure; a virtual substrate material over the substrate structure, the virtual substrate material having a virtual substrate lattice constant and a virtual substrate lattice structure; at least one first fin extending above a region of the virtual substrate, the first fin including a first material with a strained first material lattice structure substantially conforming to the virtual substrate lattice structure, the first material having a first material lattice constant different from the virtual substrate lattice constant. In one embodiment, the portion may be a first portion, and the device may further include at least one second fin extending above a second region of the virtual substrate, the second fin including a second material having a second strained lattice structure substantially conforming to the virtual substrate lattice structure, the second material having a second material lattice constant different from the virtual substrate lattice constant and different from the first material lattice constant.

In a further embodiment, the strained first material lattice structure has a tensile strained lattice structure, and the strained second material lattice structure has a compressively strained lattice structure. In one example, the virtual substrate material may be silicon-germanium. In a further example, the first material may be silicon. In yet a further example, the second material may be germanium.

Reference is made below to the drawings, which are not drawn to scale for ease of understanding, wherein the same reference numbers used throughout different figures designate the same or similar components.

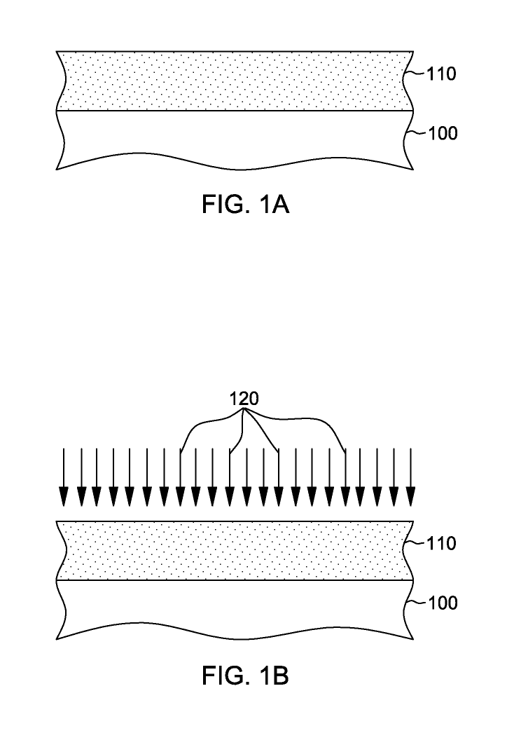

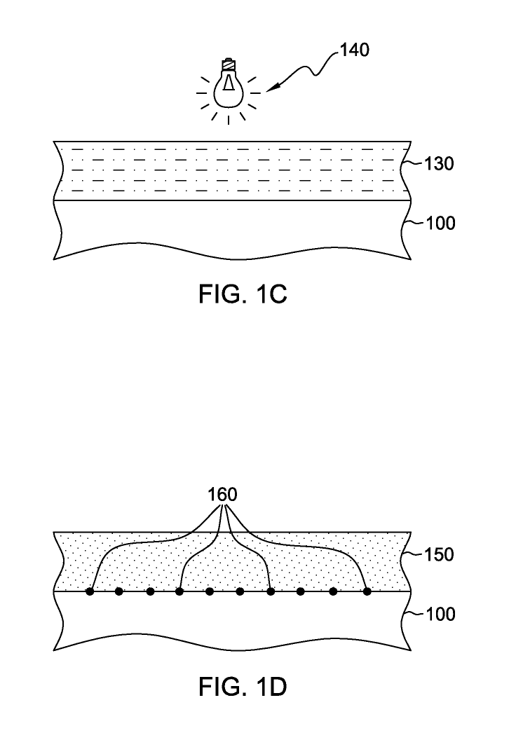

FIGS. 1A-1D depict one embodiment of a process for forming a virtual substrate material over a substrate structure. By way of example, the process illustrated depicts forming a relaxed silicon-germanium virtual substrate over a silicon substrate; it is to be understood that other types of virtual substrate materials may be formed over a silicon substrate or other type of substrate. FIG. 1A depicts, by way of example, a silicon substrate structure 100 over which a layer of silicon-germanium 110 is provided. Silicon-germanium layer 110 may be provided by deposition of Si₁₋ₓGeₓ over silicon substrate structure 100 to epitaxially grow silicon-germanium layer 110.

FIG. 1B depicts silicon substrate structure 100 and silicon-germanium layer 110 undergoing an implantation process 120. By way of example, implantation process 120 may include implanting carbon into the silicon-germanium layer, resulting in a silicon-germanium-carbon layer. Following implantation process 120, the carbon content of the silicon-germanium-carbon layer may be about 0.05% to 3% of the layer. Although it may be possible to form a desired virtual substrate material with a deposition of one silicon-germanium layer and one implantation of carbon into the silicon-germanium layer, a desired virtual substrate material may be more easily achieved by repeating these steps several times to form multiple layers of epitaxially deposited silicon-germanium and multiple layers of silicon-germanium-carbon. With each layer of silicon-germanium deposited, the amount of germanium silicon-germanium may be increased until a desired ratio is achieved. The formation of multiple layers may facilitate forming a virtual substrate with few to no threading dislocations or other defects near or at the outer surface of the virtual substrate. For ease of illustration only, one silicon-germanium layer 110 and one implantation process 120 are depicted in FIG. 1B.

FIG. 1C depicts an embodiment of a silicon-germanium-carbon layer 130, formed over silicon substrate 100 by the implantation process described with FIG. 1B, undergoing an annealing process 140. Annealing silicon-germanium-carbon layer 130 may enhance the formation of silicon-carbon crystals, which may further facilitate formation of a relaxed silicon-germanium layer above silicon substrate 100. Annealing process 140 may require annealing silicon-germanium-carbon layer 130 between about 800° and about 1000° C.

FIG. 1D depicts an embodiment of a virtual substrate material 150 of relaxed silicon-germanium resulting from an annealing process as described above. In the embodiment depicted, defects 160 in the lattice structure of virtual substrate material 150, such as threading dislocations, may be confined to the interface between silicon substrate 100 and virtual substrate material 150, leaving the outer surface of virtual substrate material 150 nearly or completely defect-free.

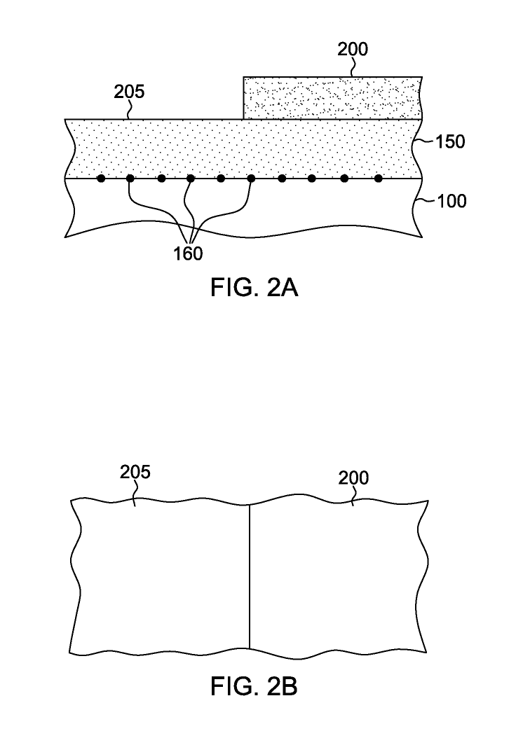

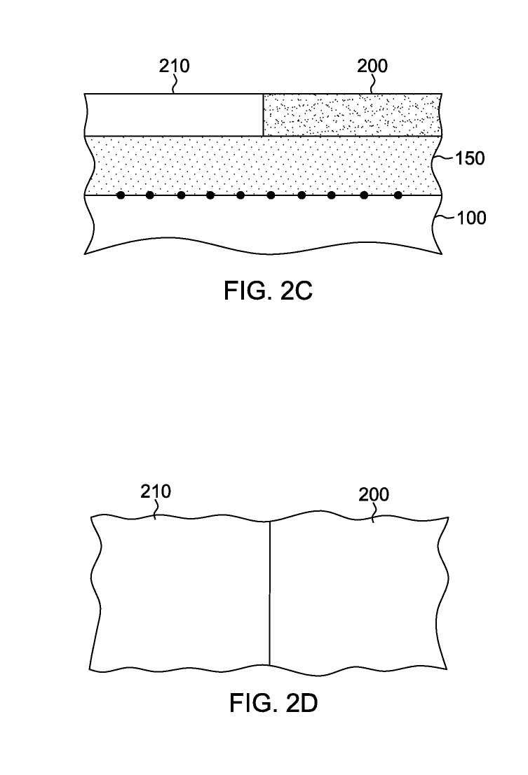

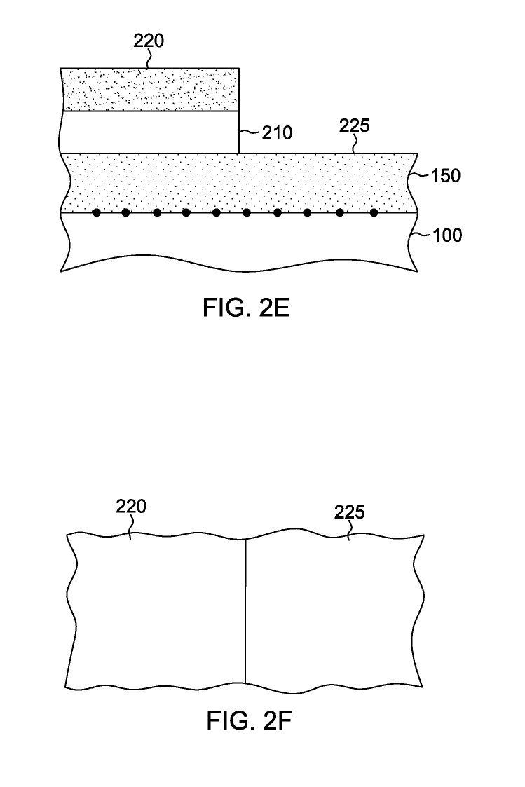

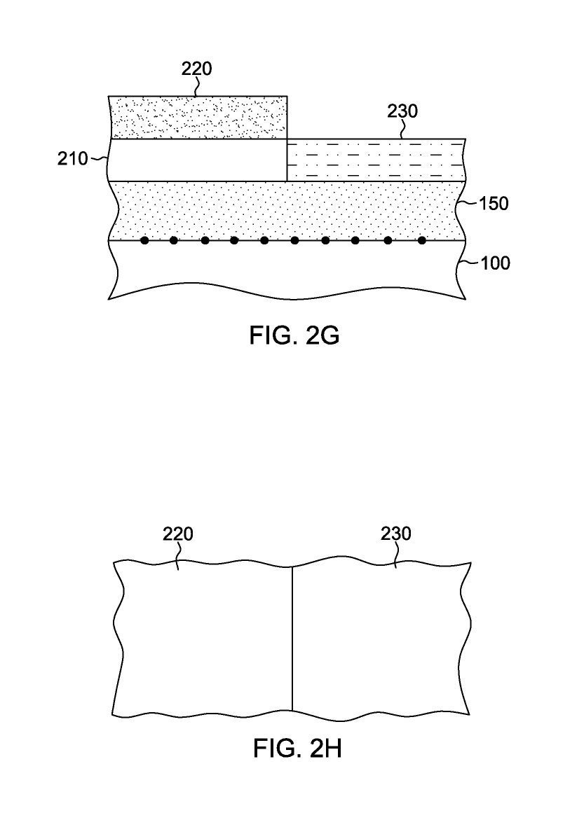

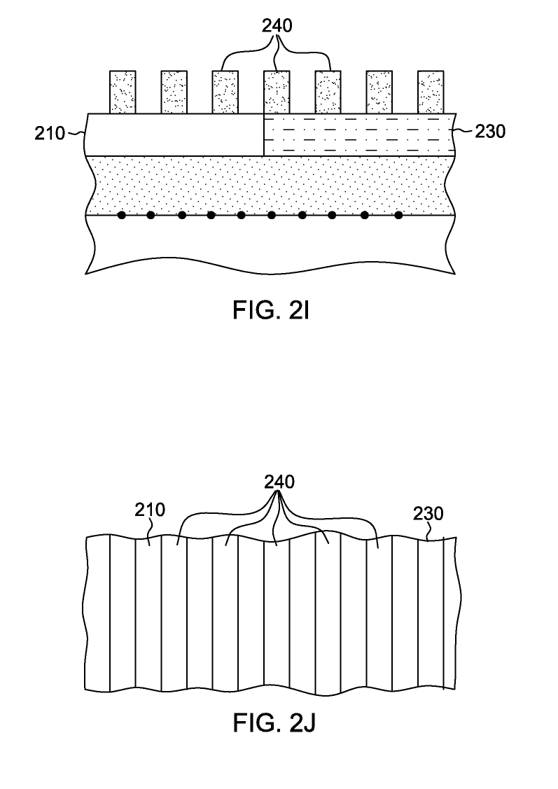

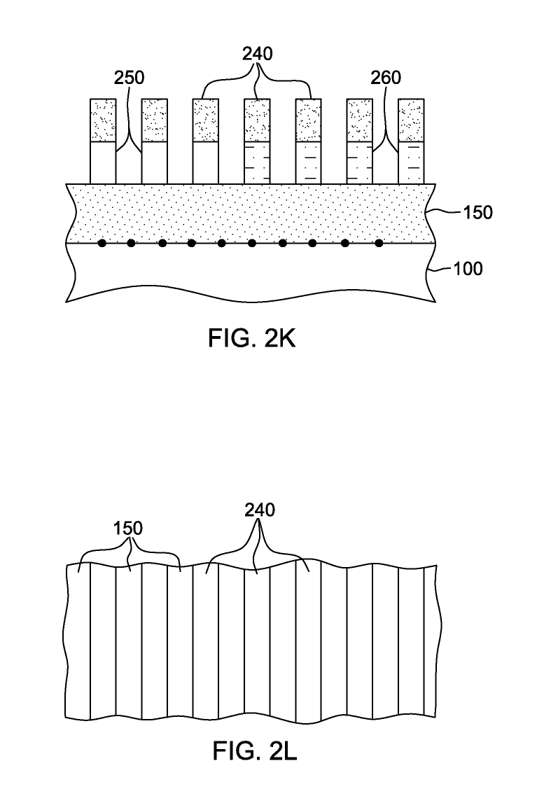

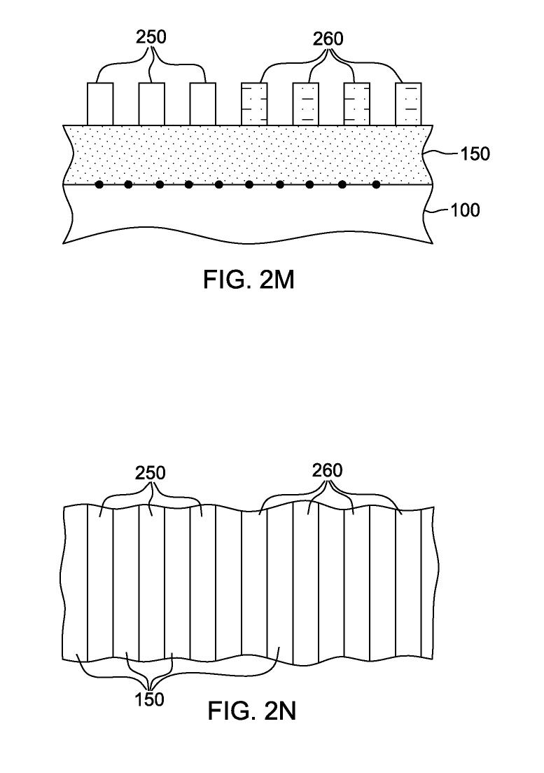

FIGS. 2A-2N depict an embodiment of a method for forming strained fin structures over a virtual substrate material, such as a relaxed silicon-germanium virtual substrate material 150 over a silicon substrate structure 100. Virtual substrate material 150 may be provided as described in conjunction with FIGS. 1A-1D, or may alternatively be provided by other methods. It may be understood that silicon substrate structure 100 and relaxed silicon-germanium virtual substrate material 150 are depicted by way of example only, and that other substrate structures and virtual substrate materials may be alternatively used in practicing the methods described herein for forming strained fin structures.

FIG. 2A depicts a cross-section view of an embodiment of a virtual substrate material 150 over a substrate structure 100 after a first mask 200 has been provided over a portion of virtual substrate material 150, leaving a first region 205 of virtual substrate material 150 exposed. FIG. 2B depicts FIG. 2A in plan view, illustrating first mask 200 and first portion 205 of the virtual substrate material. Virtual substrate material 150 has a virtual substrate lattice structure, which is determined, in part, by its chemical composition. The lattice structure of a virtual substrate material may be determined, in part, by its lattice constant, which may in turn be determined as a function of one or more lattice constants of the elements comprising the virtual substrate material. By way of example, relaxed silicon-germanium (Si₁₋ₓGeₓ) may have a lattice constant a_{Si1-xGex} determined from a lattice constant a_{Si} for silicon and a lattice constant a_{Ge} for germanium, where a_{Si1-xGex}=(1−x)a_{Si}-xa_{Ge}. Generally a_{Si1-xGex} will be greater than a_{Si} and less than a_{Ge}; thus, the lattice structure of relaxed silicon-germanium generally has a larger lattice spacing than the lattice structure of silicon, and a smaller lattice spacing than the lattice structure of germanium. By way of further example, a relaxed silicon-germanium virtual substrate material may ideally have a silicon-to-germanium ratio of about 1:1, or about 50% silicon to 50% germanium (Si_{0.5}Ge_{0.5}). At this ratio, the lattice constant of a relaxed silicon-germanium virtual substrate may be the average of the lattice constants of silicon and germanium. This ratio of silicon to germanium may further facilitate forming both n-type tensile strained fins and p-type compressively strained fins.

FIG. 2C depicts a cross-section view of substrate 100, virtual substrate material 150, and first mask 200 after a first material 210 has been provided over the first region of virtual substrate material 150. FIG. 2D depicts FIG. 2C in plan view, illustrating first mask 200 and first material 210. First material 210 may, for example, be provided by an epitaxial deposition process, resulting in epitaxial growth of the first material 210 over virtual substrate material 150. As first material 210 is epitaxially grown, it may conform to and acquire the lattice structure of virtual substrate material 150. Further, when first material 210 has a lattice constant that is different from the lattice constant of virtual substrate 150, first material 210 may acquire a strained lattice structure through conforming to the virtual substrate lattice structure. For example, where first material 210 has a smaller lattice constant than the lattice constant of virtual substrate material 150, first material 210 may acquire a tensile strained lattice structure. This may occur, for instance, where virtual substrate material 150 is relaxed silicon-germanium and first material 210 is silicon, as depicted in FIGS. 2C and 2D, as silicon has a smaller lattice constant than that of relaxed silicon-germanium. In another example, where first material 210 has a larger lattice constant than the lattice constant of virtual substrate material 150, first material 210 may acquire a compressively strained lattice structure. This may occur, for instance, where virtual substrate material 150 is relaxed silicon-germanium and first material 210 is germanium, as germanium has a larger lattice constant than that of relaxed silicon-germanium.

FIG. 2E depicts a cross-section view of substrate 100, virtual substrate material 150 after the first mask has been removed, and first material 210 after a second mask has been provided over first material 210, leaving a second portion 225 of virtual substrate 150 exposed. FIG. 2F depicts FIG. 2E in plan view, illustrating second mask 220 and second portion 225 of the virtual substrate.

FIG. 2G depicts a cross-section view of substrate 100, second mask 220 over first material 210, and virtual substrate material 150 after a second material 230 has been provided over the second portion of virtual substrate 150. FIG. 2H depicts FIG. 2G in plan view, illustrating second mask 220 and second material 230. Similarly to the first material, as described above, second material 210 may, for example, be provided by an epitaxial deposition process, resulting in epitaxial growth of second material 230 over virtual substrate material 150. As second material 230 is epitaxially grown, it may conform to and acquire the lattice structure of virtual substrate material 150. Further, when second material 230 has a lattice constant that is different from the lattice constant of virtual substrate material 150, second material 230 may acquire a strained lattice structure through conforming to the virtual substrate lattice structure. For example, where second material 230 has a larger lattice constant than the lattice constant of virtual substrate material 150, second material 210 may acquire a compressively strained lattice structure. This may occur, for instance, where virtual substrate material 150 is relaxed silicon-germanium and second material 210 is germanium, as depicted in FIGS. 2G and 2H, as germanium has a larger lattice constant than that of relaxed silicon-germanium. In another example, where second material 230 has a smaller lattice constant than the lattice constant of virtual substrate material 150, second material 230 may acquire a tensile strained lattice structure.

FIG. 2I depicts a cross-section view of substrate 100, virtual substrate material 150, and first material 210 and second material 230 after a fin pattern 240 has been provided over first material 210 and second material 230. FIG. 2J depicts FIG. 2I in plan view, illustrating fin pattern 240 over first material 210 and second material 230. Fin pattern 240 may be provided, for example, by depositing a photo-sensitive material over first material 210 and second material 230, followed by a photo-lithographic process to lift off a portion of the photo-sensitive material, leaving behind fin pattern 240. Alternative processes for providing a fin pattern may be possible. By way of example only, fin pattern 240 may be designed for formation of equally sized or equally spaced fin structures, as depicted in FIGS. 2I and 2J. However, alternative fin patterns may also be possible, such as, for instance, a first pattern that forms wider fins over the first material and a second pattern to form narrower fins over the second material.

FIG. 2K depicts a cross-section view of substrate 100 and virtual substrate material 150 with first material fins 250 and second material fins 260 extending above virtual substrate material 150, the fins resulting from an etching process. FIG. 2L depicts FIG. 2K in plan view, illustrating unetched fin pattern 240, covering the first material fins and second material fins (not visible in FIG. 2L), and unetched virtual substrate material 150. In one example, the etch process may be an anisotropic etch process that etches a portion of the first material and the second material without etching virtual substrate material 150. Fin pattern 240 may facilitate the etching process by protecting the portions of the first material and second material designed to define one or more desired fin structures. By way of example, the anisotropic etch process may be a RIE dry etch process. The fins 250, 260 resulting from the etching process may retain the strained lattice structure of the respective materials prior to the etching process. Thus, by way of example, where first material fins 250 are formed from the material with a tensile strained lattice structure, first material fins 250 may similarly be tensile strained. This tensile strain may enhance electron mobility in first material fins 250, as may be desirable for n-type fin structures. Similarly by way of example, where second material fins 260 are formed from the material with a compressively strained lattice structure, second material fins 260 may be compressively strained. This compressive strain may enhance hole mobility in second material fins 260, as may be desirable for p-type fin structures.

FIG. 2M depicts a cross-section view of first material fins 250 and second material fins 260 extending above virtual substrate material 150 after the remaining fin pattern has been removed. FIG. 2N depicts FIG. 2M in plan view, illustrating one possible example of first material fins 250 and second material fins 260 above virtual substrate 150. FIG. 2M further illustrates an embodiment of a device with a substrate 100, a virtual substrate material 150 with a virtual substrate lattice structure over substrate 100, and at least one fin 250 extending above a first portion of virtual substrate material 150, where the at least one fin 250 is formed of a first material having a first strained lattice structure that substantially conforms to the lattice structure of virtual substrate material 150. By way of example and as illustrated, the device may further have at least one second fin 260 extending above a second portion of virtual substrate material 150, where the at least one second fin 260 is formed of a second material having a second strained lattice structure that substantially conforms to the lattice structure of virtual substrate material 150. By way of further example, first fin(s) 250 may be a material, such as silicon, with a tensile strained lattice structure. By way of further example, second fin(s) 260 may be a material, such as germanium, with a compressively strained lattice structure. The device may thus have both n-type fins with enhanced electron mobility and p-type fins with enhanced hole mobility formed over a virtual substrate material 150.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. A method comprising:
fabricating a strained fin structure, the fabricating comprising:
providing a virtual substrate material over a substrate structure, the virtual substrate material having a virtual substrate lattice structure and a virtual substrate lattice constant;
providing a first material over a region of the virtual substrate material, the first material having a first material lattice constant different from the virtual substrate lattice constant, the first material acquiring a strained first material lattice structure via, in part, conforming to the virtual substrate lattice structure; and
etching a first fin pattern into the first material, the first fin pattern including at least one first material fin extending above the region of the virtual substrate material.

2. The method of claim 1, wherein the region of the virtual substrate material is a first region, and the method further comprises providing a second material over a second region of the virtual substrate material, the second material having a second material lattice constant different from the virtual substrate lattice constant and the first material lattice constant, the second material acquiring a strained second material lattice structure via, in part, conforming to the virtual substrate lattice structure, and wherein the etching further comprises etching a second fin pattern into the second material, the second fin pattern including at least one second material fin extending above the second region of the virtual substrate material.

3. The method of claim 2, wherein one of the strained first material lattice structure or the strained second material lattice structure is a tensile strained lattice structure, and the other of the strained first material lattice structure or the strained second material lattice structure is a compressively strained lattice structure.

4. The method of claim 3, wherein the first material lattice constant is smaller than the virtual substrate lattice constant, and the strained first material lattice structure is the tensile strained lattice structure.

5. The method of claim 3, wherein the second material lattice constant is larger than the virtual substrate lattice constant, and the strained second material lattice structure is the compressively strained lattice structure.

6. The method of claim 3, wherein the virtual substrate material comprises relaxed silicon-germanium (Si₁₋ₓGeₓ) material.

7. The method of claim 6, wherein silicon to germanium in the relaxed silicon-germanium is about 50% silicon to 50% germanium.

8. The method of claim 6, wherein providing the virtual substrate material comprises epitaxially growing a silicon-germanium layer over the substrate structure, implanting carbon into the silicon-germanium layer to form a silicon-germanium-carbon layer, and annealing the silicon-germanium-carbon layer to form the relaxed silicon-germanium material.

9. The method of claim 8, wherein epitaxially growing the silicon-germanium material further comprises epitaxially growing a plurality of silicon-germanium layers, and implanting carbon further comprises implanting carbon into one or more of the plurality of silicon-germanium layers to facilitate forming the relaxed silicon-germanium material.

10. The method of claim 3, wherein the first material comprises silicon, and the first material acquires the tensile strained lattice structure.

11. The method of claim 3, wherein the second material comprises germanium, and the second material acquires the compressively strained lattice structure.

12. The method of claim 3, wherein the providing the first material comprises epitaxially growing the first material on the first region of the virtual substrate material, and wherein the providing the second material comprises epitaxially growing the second material on the second region of the virtual substrate material.

13. The method of claim 3, wherein the etching comprises anisotropically etching the first fin pattern and the second pattern into the first material and the second material, respectively.

14. A device, comprising:
a substrate structure;
a virtual substrate material over the substrate structure, the virtual substrate material having a virtual substrate lattice constant and a virtual substrate lattice structure;
at least one first fin extending above a region of the virtual substrate material, the first fin comprising a first material with a strained first material lattice structure substantially conforming to the virtual substrate lattice structure, the first material having a first material lattice constant different from the virtual substrate lattice constant.

15. The device of claim 14, wherein the region is a first region, and the device further comprises at least one second fin extending above a second region of the virtual substrate material, the second fin comprising a second material with a strained second material lattice structure substantially conforming to the virtual substrate lattice structure, the second material having a second material lattice constant different from the virtual substrate lattice constant.

16. The device of claim 15, wherein the strained first material lattice structure comprises a tensile strained lattice structure, and the strained second material lattice structure comprises a compressively strained lattice structure.

17. The device of claim 16, wherein the virtual substrate material comprises a relaxed silicon-germanium (Si₁₋ₓGeₓ) material.

18. The device of claim 17, wherein silicon to germanium in the relaxed silicon-germanium material is about 50% silicon to 50% germanium.

19. The device of claim 16, wherein the first material comprises silicon.

20. The device of claim 16, wherein the second material comprises germanium.
